(19) United States
(12) Patent Application Publication
(10) Pub. No.: US 2008/0291634 A1
(43) Pub. Date: Nov. 27, 2008

(54) THERMAL INTERCONNECT AND INTERFACE MATERIALS, METHODS OF PRODUCTION AND USES THEREOF

(76) Inventors: Martin W. Weiser, Liberty Lake, WA (US); Kikue S. Burnham, San Ramon, CA (US); De-Ling Zhou, Sunnyvale, CA (US); Roger Y. Leung, San Jose, CA (US); Jan Nedbal, San Jose, CA (US); Ravi Rastogi, Liberty Lake, WA (US)

Correspondence Address: HONEYWELL INTERNATIONAL INC., 101 COLUMBIA ROAD, P O BOX 2245, MORRISTOWN, NJ, 07962-2245, US

(21) Appl. No.: 12/124,998

(22) Filed: May 21, 2008

Related U.S. Application Data
(60) Provisional application No. 60/939,441, filed on May 22, 2007.

(51) Int. Cl. H05K 7/20

(52) U.S. Cl. 361/708; 361/712

(57) ABSTRACT

Thermal interface materials are disclosed that include at least one matrix material component, at least one high conductivity filler component, at least one solder material; and at least one material modification agent, wherein the at least one material modification agent improves the thermal performance, compatibility, physical quality or a combination thereof of the thermal interface material. Methods of forming thermal interface materials are also disclosed that include providing each of the at least one matrix material component, at least one high conductivity filler, at least one solder material and at least one material modification agent, blending the components; and optionally curing the components pre- or post-application of the thermal interface material to the surface, substrate or component. Also, thermal interface materials are disclosed that include at least one matrix material component, at least one high conductivity filler component, at least one solder material; and at least one material modification agent, wherein the at least one material modification agent at least one modified thermal filler profile.

This application is a United States Utility Application based on U.S. Provisional Application Ser. No. 60/939,441 filed on May 22, 2007, which is commonly-owned and incorporated herein in its entirety.

### FIELD OF THE SUBJECT MATTER

The field of the subject matter is thermal interconnect systems, thermal interface systems and interface materials in electronic components, semiconductor components and other related layered materials applications.

### BACKGROUND

Electronic components are used in ever increasing numbers in consumer and commercial electronic products. Examples of some of these consumer and commercial products are televisions, flat panel displays, personal computers, gaming systems, Internet servers, cell phones, pagers, palm-type organizers, portable radios, car stereos, or remote controls. As the demand for these consumer and commercial electronics increases, there is also a demand for those same products to become smaller, more functional, and more portable for consumers and businesses.

As a result of the size decrease in these products, the components that comprise the products must also become smaller. Examples of some of those components that need to be reduced in size or scaled down are printed circuit or wiring boards, resistors, wiring, keyboards, touch pads, and chip packaging. Products and components also need to be prepackaged, such that the product and/or component can perform several related or unrelated functions and tasks Examples of some of these “total solution” components and products comprise layered materials, mother boards, cellular and wireless phones and telecommunications devices and other components and products, such as those found in US Patent and PCT Application Serial Nos. 60/396,294 filed Jul. 15, 2002, 601294433 filed May 30, 2001, 10/519,337 filed Dec. 22, 2004, 10/551,305 filed Sep. 28, 2005, 10/465,968 filed Jun. 26, 2003 and PCT/US02/17331 filed May 30, 2002, which are all commonly owned and incorporated herein in their entirety.

Electronic components, therefore, are being broken down and investigated to determine if there are better building materials and methods that will allow them to be scaled down and/or combined to accommodate the demands for smaller electronic components. In layered components, one goal appears to be decreasing the number of the layers while at the same time increasing the functionality and durability of the remaining layers and surface/support materials. This task can be difficult, however, given that several of the layers and components of the layers should generally be present in order to operate the device.

Also, as electronic devices become smaller and operate at higher speeds, energy emitted in the form of heat increases dramatically with heat flux often exceeding 100 W/cm². A popular practice in the industry is to use thermal interface materials alone or on a carrier in such devices to transfer the heat dissipated across physical interfaces and finally to the ambient atmosphere Most common types of thermal interface materials are thermal greases, phase change materials, and elastomer tapes. Thermal greases and phase change materials have lower thermal resistance than elastomer tapes because of the ability to be spread in very thin layers and provide intimate contact between adjacent surfaces. Typical thermal impedance values range between 0.1-1.6° C.-cm²/W since this is a strong function of the bond line thickness However, a serious drawback of thermal grease is that thermal performance deteriorates significantly after thermal cycling, such as from −65° C. to 150° C., or after power cycling when used in VLSI chips. The most common thermal greases use silicone oils as the carrier or matrix. It has also been found that the performance of these materials deteriorates when large deviations from surface planarity causes gaps to form between the mating surfaces in the electronic devices or when large gaps between mating surfaces are present for other reasons, such as manufacturing tolerances, etc. When the heat transferability of these materials breaks down, the performance and reliability of the electronic device in which they are used is adversely affected.

When polymer solder materials are utilized as level 1 thermal interface materials or TIM1s, these materials should wet the die back, heat spreader and high conductivity filler surfaces to give good thermal performance. To increase the thermal performance of the polymer solders, both inorganic and rosin moderately activated (RMA) fluxes have been added to the TIM in order to remove oxides from the solder, die back, spreader, and/or fillers to improve wetting by the solder of these surfaces. But these fluxes can result in a significant degradation of the polymer matrix and therefore the overall performance of the TIM.

Thus, there is a continuing need to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) produce materials and layers that are more compatible with other layers, surfaces and support materials at the interface of those materials; d) develop reliable methods of producing desired thermal interconnect materials, thermal interface materials and layered materials and components/products comprising contemplated thermal interface and layered materials; e) develop materials that possess a high thermal conductivity and a high mechanical compliance; and f) effectively reduce the number of production steps necessary for a package assembly, which in turn results in a lower cost of ownership over other conventional layered materials and processes.

### SUMMARY

Thermal interface materials are disclosed that include at least one matrix material, at least one high conductivity filler component, at least one solder material; and at least one material modification agent, wherein the at least one material modification agent improves the thermal performance, compatibility, physical quality or a combination thereof of the thermal interface material.

Methods of forming thermal interface materials are also disclosed that include providing each of the at least one matrix material, at least one high conductivity filler, at least one solder material and at least one material modification agent, blending the components; and optionally curing the components pre- or post-application of the thermal interface material to the surface, substrate or component.

Also, thermal interface materials are disclosed that include at least one matrix material, at least one high conductivity filler component, at least one solder material; and at least one material modification agent, wherein the at least one material modification agent includes at least one modified thermal filler profile.

### BRIEF DESCRIPTION OF THE FIGURE

FIG. 1 shows a plot of a contemplated inhibitor amount versus a contemplated cross-linker amount and the related material properties.

FIG. 2 shows particle size distributions for the different powders were measured using a Microtrac X100 particle size analyzer.

FIG. 3 shows the particle size distributions of representative samples used for the study in Example 6.

FIG. 4 shows a three-layer sandwich 400 composed of a Cu heat spreader 410 plated with Ni and Au, the thermal interface material 420, and a Si die 430 that had been sputtered with Ti, Ni, and finally Au is created by stacking the layers and curing the stack in a fixture at 30 psi applied pressure.

FIG. 5 shows the thermal impedance of several contemplated samples.

FIG. 6 shows the results of the cut-bar and flash diffusivity methods utilized to obtain the thermal impedance data for several contemplated samples.

FIG. 7 shows that the viscosity of the 50A formulation does not change during room temperature (nominally 21° C.) storage of nearly 30 hrs.

FIG. 8 shows that the 50A formulation does not degrade significantly during high temperature aging.

FIG. 9 also shows that the 50A formulation does not degrade significantly during highly accelerated stress testing (HAST).

### DETAILED DESCRIPTION

A suitable interface material or component should conform to the mating surfaces (deforms to fill surface contours and “wets” the surface), possess a low bulk thermal resistance and possess a low contact resistance. Bulk thermal resistance can be expressed as a function of the material's or component's thickness, thermal conductivity and area. Contact resistance is a measure of how well a material or component is able to transfer heat across the interface which is largely determined by the amount and type of contact between the two materials. One of the goals of the materials and methods described herein is to minimize contact resistance without a significant loss of performance from the materials. The thermal resistance of an interface material or component can be shown as follows:

Θ_{interface}=t/k+Θ_{c1}+Θ_{c2} Equation 1
where Θ is the overall thermal resistance,
   t is the material thickness,
   k is the thermal conductivity of the material
   Θ_{c1} is the contact resistance to the first surface
   Θ_{c2} is the contact resistance to the second surface

The term “t/k” represents the thermal resistance of the bulk material and “Θ_{c1}” and “Θ_{c2}” represent the thermal contact resistance at the two surfaces. A suitable interface material or component should have a low bulk resistance and a low contact resistance at the mating surfaces.

Many electronic and semiconductor applications require that the interface material or component accommodate deviations from surface flatness resulting from manufacturing and/or warpage of components because of coefficient of thermal expansion (CTE) mismatches.

A material with a low value for k, such as thermal grease, performs well if the interface is thin, i.e. the “t” value is low with most performing best when “t” is less than 0.050 mm and in some cases less than 0.025 mm. If the interface thickness increases by as little as 0.050 mm, the overall thermal performance can drop dramatically. Also, for such applications, differences in CTE between the mating components cause the gap to expand and contract due to warpage with each temperature or power cycle. This variation of the interface thickness can cause pumping of fluid interface materials (such as grease) away from the interface, thereby leaving an air gap which has very poor thermal transfer properties.

Interfaces with a larger area are more prone to deviations from surface planarity as manufactured. To optimize thermal performance, the interface material should be able to conform to non-planar surfaces and thereby achieve lower contact resistance. As used herein, the term “interface” means a couple or bond that forms the common boundary between two parts of matter or space, such as between two molecules, two backbones, a backbone and a network, two networks, etc. An interface may comprise a physical attachment of two parts of matter or components or a physical attraction between two parts of matter or components, including bond forces such as covalent and ionic bonding, Van der Waals, hydrogen bonding and non-bond forces such as electrostatic, coulombic, and/or magnetic attraction. Contemplated interfaces include those interfaces that are formed with bond forces, such as covalent and metallic bonds; however, it should be understood that any suitable adhesive attraction or attachment between the two parts of matter or components is preferred.

Optimal interface materials and/or components possessing a high thermal conductivity and a high mechanical compliance, e.g. will yield elastically or plastically at the local level when force is applied. High thermal conductivity reduces the first term of Equation 1 while high mechanical compliance prevents the second and third terms from increasing under stress. The layered interface materials and the individual components of the layered interface materials described herein accomplish these goals. When properly produced, the thermal interface component described herein will span the distance between the mating surfaces, e.g. that of the heat spreader material and the silicon die component, thereby allowing a continuous high conductivity path from one surface to the other surface.

As mentioned earlier, several goals of thermal interface materials, layered interface materials and individual components described herein are to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) produce materials and layers that are more compatible with other layers, surfaces and support materials at the interface of those materials; d) develop reliable methods of producing desired thermal interconnect materials, thermal interface materials and layered materials and components/products comprising contemplated thermal interface and layered materials; e) develop materials that possess a high thermal conductivity and a high mechanical compliance; and f) effectively reduce the number of production steps necessary for a package assembly, which in turn results in a lower cost of ownership over other conventional layered materials and processes.

Materials and modified surfaces/support materials for pre-attached/pre-assembled and stand alone thermal solutions and/or IC (interconnect) packages are provided herein. In addition, thermal solutions and/or IC packages that comprise one or more of these materials and modified surface/support materials described herein are contemplated. Ideally, contemplated components of a suite of thermal interface materials exhibit low thermal resistance, high thermal performance and maximum surface wetting for a wide variety of interface conditions and demands. Thermal interface materials contemplated herein can be used to attach the heat generating electronic devices (e.g. the computer chip or silicon die) to the heat dissipating structures (e.g. heat spreaders, heat sinks). The performance of the thermal interface materials is one of the most important factors in ensuring adequate and effective heat transfer in these devices. The thermal interface materials described herein are novel in that they combine components in amounts not yet contemplated or disclosed in other related art.

As mentioned, the thermal interface materials and modified surfaces described herein, which are also described in U.S. patent application Ser. No. 11/493,778 and PCT Application No.: PCT/US2007/073783 entitled “Synergistically-Modified Surface Profiles for Use With Thermal Interconnect and Interface Materials, Methods of Production and Uses Thereof”, which is commonly-owned and incorporated herein by reference in its entirety, may be utilized in total solution packaging, such as in a combo-spreader or layered component. The layered interface materials and the individual components of the layered interface materials described herein accomplish these goals.

Specifically, thermal interface materials may comprise at least one matrix material component, at least one high conductivity filler component, at least one solder material and at least one material modification agent, wherein the at least one material modification agent improves the thermal performance, compatibility, physical quality or a combination thereof of the thermal interface material. In some embodiments, thermal interface materials are disclosed that include at least one matrix material, at least one high conductivity filler component, at least one solder material; and at least one material modification agent, wherein the at least one material modification agent includes at least one modified thermal filler profile.

Methods of forming these thermal interface materials comprise providing each of the at least one matrix material component, at least one high conductivity filler, at least one solder material and at least one material modification agent, blending the components and optionally curing the components pre- or post-application of the thermal interface material to the surface, substrate or component. In some embodiments, the cured thermal interface material is crosslinked according to procedures outlined herein.

The at least one matrix material component may comprise any suitable material, including silicon-based components, siloxane-based components, silicone-based components, organic oils, the organic component of PCM45 and/or PCM45F, which is a high conductivity phase change material manufactured by Honeywell International Inc., or curable and/or crosslinkable polymers. In some embodiments, the at least one matrix material component further comprises an epoxy component. It should be understood that the phrase “matrix material component” means that or those components that ultimately form the matrix material of the thermal interface material. The phrase “matrix material” means that material that is in the desired thermal interface material. Specific applications of the thermal interface material may require that it be cured or remain uncured—and in which ever instance, the matrix material is that material forming the matrix to hold the other components, such as the at least one high conductivity filler, the at least one solder material and the at least one material modification agent.

The at least one matrix material component is chosen based on the application. For example, at least one organic oil may be utilized in order to provide the thermal interface material with better gap-filling properties. At least one phase change material may be utilized in order to provide a more versatile matrix material, which can easily transform from soft gel to compliant material. Crosslinkable molecules and polymers may also be utilized in order to provide a matrix material that can be strategically cured to provide a stable layered material, along with superior heat transfer properties. Contemplated matrix materials comprise siloxane-based polymers, silicone-based polymers, silicone oils, and organic oils, alone or in combination. In some embodiments, contemplated oils comprise plant-based oils (e.g. corn oil), mineral oils and synthetic oils, such as MIDEL 1731, which has properties close to silicone/mineral oil. Organic oils can in many cases have similar properties as thermal greases. However, many organic oils will partially cure upon heating which will slow or prevent the pump-out phenomenon that the silicone based greases experience.

Phase-change materials that are contemplated herein comprise waxes, polymer waxes or mixtures thereof, such as paraffin wax. Paraffin waxes are a mixture of solid hydrocarbons having the general formula CₙH₂ₙ₊₂ and having melting points in the range of about 20° C. to 145° C. Examples of some contemplated melting points are about 45° C. and 60° C. Thermal interface components that have melting points in this range are PCM45 and PCM60HD—both manufactured by Honeywell International Inc. Polymer waxes are typically polyethylene waxes, polypropylene waxes, and have a range of melting points from about 40° C. to 160° C.

PCM45 comprises a thermal conductivity of about 3.0 W/m-K, a thermal resistance of about 0.25° C.-cm²/W at 0.05 mm thickness, is typically applied at a thickness of about 0.25 mm and comprises a soft material above the phase change temperature of approximately 45° C., flowing easily under an applied pressure of about 35 to 210 kPa. Typical characteristics of PCM45 are a) a super high packaging density of the solid fillers—over 80 weight %, b) a conductive filler, c) extremely low thermal resistance, and as mentioned earlier d) about a 45° C. phase change temperature. PCM60HD comprises a thermal conductivity of about 5.0 W/m-K, a thermal resistance of about 0.17° C.-cm²/W at 0.05 mm thickness, is typically applied at a thickness of about 0.25 mm and comprises a soft material, flowing easily under an applied pressure of about 35 to 210 kPa to give a final BLT of 0.04 mm. Typical characteristics of PCM60HD are a) a super high packaging density of the solid fillers—over 80 weight %, b) a conductive filler, c) extremely low thermal resistance, and as mentioned earlier d) about a 60° C. phase change temperature. TM200 (a thermal interface component not comprising a phase change material and manufactured by Honeywell International Inc.) comprises a thermal conductivity of about 3.0 W/m-K, a thermal resistance of below 0.20° C.-cm²/W at 0.05 mm thickness, is typically applied at a thickness of about 0.25 mm and comprises a paste that can be thermally cured to a soft gel. Typical characteristics of TMA200 are a) a super high packaging density—over 80 weight %, b) a conductive filler, c) extremely low thermal resistance, d) about a 125° C. curing temperature, and e) dispensable silicone-based thermal gel. PCM45F comprises a thermal conductivity of about 2.35 W/m-K, a thermal resistance of about 0.20° C.-cm²/W at 0.05 mm thickness, is typically used at a thickness of about 0.050 mm [application thickness is generally 0.2-0.25 mm, but it normally compresses to 0.05 mm] and comprises a soft material, flowing easily under an applied pressure of about 35 to 275 kPa. Typical characteristics of PCM45F are a) a super high packaging density—over 80 weight %, b) a conductive filler, c) extremely low thermal resistance, and as mentioned earlier d) about a 45° C. phase change temperature.

Phase change materials are useful in thermal interface component applications because they are solid at room temperature and can easily be pre-applied to thermal management components. At operation temperatures above the phase change temperature, the material is liquid and behaves like a thermal grease. The phase change temperature is the melting temperature where the material transforms from a soft solid at low temperatures to a viscous liquid at higher temperatures.

Paraffin-based phase change materials, however, have several drawbacks. On their own, they can be very fragile and difficult to handle. They also tend to squeeze out of a gap from the device in which they are applied during thermal cycling, very much like a grease. Contemplated modified paraffin polymer, polyethylene, and polypropylene wax systems described herein avoid these problems and provides significantly improved ease of handling, are capable of being produced in flexible tape or solid layer form, and do not pump out or exude under pressure. Although contemplated materials may have the same or nearly the same melt temperature as the unmodified waxes, their melt viscosity is much higher and they do not migrate easily. Moreover, contemplated thermal interface materials can be designed to be self-crosslinking, which ensures elimination of the pump-out problem in certain applications. Examples of contemplated phase change materials are malenized paraffin wax, polyethylene-maleic anhydride wax, and polypropylene-maleic anhydride wax. Contemplated materials can functionally form at a temperature between about 50 to 150° C. to form a crosslinked network.

Resin-containing interface materials and solder materials, especially those comprising silicone resins, that may also have appropriate thermal fillers can exhibit a thermal resistance of less than 0.5° C.-cm²/W at a thickness of less than 0.20 mm. Unlike thermal grease, thermal performance of the material will not degrade after thermal cycling or power cycling in IC devices because liquid silicone resins will cross link to form a soft gel upon heat activation.

Interface materials and polymer solders comprising resins, such as silicone resins, will not be “squeezed out” as thermal grease can be in use and will not display interfacial delamination during thermal cycling. The new material can be provided as a dispensable liquid paste to be applied by dispensing methods and then cured as desired. It can also be provided as a highly compliant, cured, and possibly cross-linkable elastomer film or sheet for pre-application on interface surfaces, such as heat sinks.

The starting resin mixture is polymerized via hydrosilylation reaction. The hydrosilylation reaction involves vinyl-functional siloxanes and hydride-functional siloxanes in the presence of a catalyst, such as platinum complexes or nickel complexes. The resin polymer can be thermally cured to form a compliant elastomer. In some embodiments, contemplated platinum catalysts comprise GELEST SIP6830.0, SIP6832.0, and platinum-vinylsiloxane.

Contemplated examples of vinyl silicone include vinyl terminated polydimethyl siloxanes that have a molecular weight of about 5000 to 50000. Contemplated examples of hydride functional siloxane include methylhydrosiloxane-dimethylsiloxane copolymers that have a molecular weight about 500 to 5000. Physical properties of the cured polymer can be varied from a very soft gel material at a very low crosslink density to a tough elastomer network of higher crosslink density.

As discussed, contemplated thermal interface materials comprise at least one high conductivity filler component. As used herein, “high conductivity fille” and/or “high conductivity filler component” means that the filler comprises a thermal conductivity of greater than about 15 W/m-K and in some embodiments, at least about 40 W/m-K. Optimally, it is desirable to have a filler component of not less than about 80 W/m-K thermal conductivity. In some embodiments, it may be desirable to have a filler component of not less than about 20 W/m-K. For example, contemplated Ag and Cu fillers both have thermal conductivities of greater than 300 W/m-K. The Bi42Sn solder has a conductivity of 19 W/m-K. Contemplated high conductivity filler components may take any form—as will be disclosed herein—including particles, flakes, fibers, nanofibers, tubes, powders, meshes or wires. In addition, the thermal conductivity of the thermal interface material is greater than about 2 or 3 W/m-K and in some embodiments, greater than 5 W/m-K. In other embodiments, the thermal conductivity of the thermal interface material is greater than about 10 W/m-K, and in yet other embodiments, the thermal conductivity is greater than about 20 W/m-K.

The at least one high conductivity filler component may be dispersed in the thermal interface component or mixture and the filler should advantageously have a high thermal conductivity. Contemplated high conductivity filler components also comprise silver, copper, aluminum or alloys thereof, boron nitride, aluminum spheres, aluminum nitride, silver-coated copper, silver-coated aluminum, carbon fibers, carbon fibers coated with metals, carbon nanotubes, carbon nanofibers, metal alloys, conductive polymers or other composite materials, metal-coated boron nitride, metal-coated ceramics, diamond, metal-coated diamond, graphite, metal-coated graphite and combinations thereof. Combinations of boron nitride and silver or boron nitride and silver/copper also provide enhanced thermal conductivity. Silver and silver-coated copper in amounts of at least about 40 weight percent (wt %) are particularly useful. These materials may also comprise metal flakes or sintered metal flakes. As mentioned earlier, it is contemplated that filler components with a thermal conductivity of greater than about 5 W/m-K and in some embodiments, at least about 40 or 80 W/m-K can be used. Optimally, it is desired to have a filler component of not less than about 20 W/m-K thermal conductivity. In some embodiments, the filler components comprise large silver powders (20 μm) from TECHNIC, medium silver-coated copper (9 μm) from FERRO, small silver powders (3 μm) from METALOR, or a combination thereof.

In some embodiments, the at least one high conductivity filler component comprises at least some particles having a diameter less than about 100 μm. In other embodiments, the diameter of at least some of those particles is less than about 80 μm. In yet other embodiments the diameter of at least some of those particles is less than about 40 μm. It should be understood that the phrase “at least some of those particles” or “at least some particles” means that in the group of at least one high conductivity filler component, some of the particles have the stated diameter, but other particles may have other diameters. It may also be advantageous to have the average particle diameter to be less than about 100 μm—meaning that some of the particle diameters may be greater than 100 μm and others less than about 100 μm, but the average particle diameter is less than about 100 μm.

Contemplated high conductivity filler components also may comprise reinforcement materials, such as screens, mesh, foam, cloth or combinations thereof. Contemplated mesh may comprise copper, silver, gold, indium, tin, aluminum, iron, screen, foam, cloth, graphite, carbon fibers or combinations thereof.

Thermal reinforcements, which are considered to be high conductivity filler components, comprise highly conductive metals, ceramics, composites, or carbon materials, such as low CTE materials or shape memory alloys. Metal or other highly conductive screen, mesh, cloth, or foam are used to enhance thermal conductivity, tailor CTE, adjust BLT, and/or modify modulus and thermal fatigue life of the TIM. Examples include Cu, Al and Ti foam (e.g. 0.025 to 1.5 mm pore size with 30-90 vol % porosity from Mitsubishi), Cu or Ag mesh or screen (e.g. wire diameter 0.05-0.15 mm, 100-145 mesh from McNichols Co), or carbon/graphite cloth (e.g. 135 μm² plain weave, 0.25 mm thick, from US Composites).

The thermal reinforcement can be treated in a number of ways to improve the performance of the TIM. The reinforcement can be pressed or rolled to reduce the thickness and whence the BLT while also increasing the area density of the reinforcement, this is particularly effective with Cu screen as described above. The surface of the reinforcement can be treated to slow the formation of intermetallic compounds due to reaction with the solder component (e.g. plating a Cu mesh with Ni). It can also be treated to enhance the wetting of the reinforcement by the solder component (e.g. Ni plating of carbon/graphite cloth or removal of oxides by methods such as exposure to forming gas (hydrogen in nitrogen or argon) at elevated temperature, wash with an acid, or coating with a flux). A flexible frame (e.g. polymer, carbon/graphite, ceramic, metal, composite or other flexible frame) can be used to divide the TIM area into smaller areas that behave independently from their neighbors to compensate for interfacial shear loading issues due to CTE mismatch effects with large size die.

High conductivity filler components may be coated utilizing any suitable method or apparatus, including coating the high conductivity filler components with solder in the molten state, by coating utilizing plasma spray, by plating or by a combination thereof.

In contemplated embodiments of thermal interface materials, it is also desirable to include at least one solder material. The solder material may comprise any suitable solder material or metal, such as indium, silver, copper, aluminum, tin, bismuth, lead, gallium and alloys thereof, but it is preferred that the solder material comprise indium or indium-based alloys. Although lead is considered one of the contemplated solder materials, it should be understood that most modern materials no longer include lead as a viable component, primarily because of environmental concerns. Lead-free solders, or those solders that contain less than 100 ppm of lead, are viewed as more viable and desirable solders moving forward in the industry.

Solder materials that are dispersed in the resin mixture are contemplated to be any suitable solder material for the desired application. Preferred solder materials are indium tin (InSn) alloys, indium silver (InAg) alloys, indium-bismuth (InBi) alloys, tin indium bismuth (SnInBi), indium tin silver zinc (in SnAgZn), indium-based alloys, tin silver copper alloys (SnAgCu), tin bismuth and alloys (SnBi), and gallium-based compounds and alloys. Especially preferred solder materials are those materials that comprise indium. The solder may or may not be doped with additional elements to promote wetting to the heat spreader or die backside surfaces.

In some embodiments, the bismuth-tin alloys comprise less than about 60 weight percent (wt %) of tin. In other embodiments, the bismuth-tin alloys comprise between about 30 and 60 wt % of tin. In some embodiments, the tin-indium-bismuth alloys comprise less than about 80 wt % of tin, less than about 50 wt % of indium and less than about 15 wt % of bismuth. In other embodiments, the tin-indium-bismuth alloys comprise between about 40-80 wt % of tin, between about 10-50 wt % of indium and about 2-15 wt % of bismuth. In some embodiments, indium-tin-silver-zinc alloys comprise less than 65 wt % of indium, less than about 65 wt % of tin, less than about 10 wt % of silver and less than about 10 wt % of zinc. In other embodiments, indium-tin-silver-zinc alloys comprise about 35-65 wt % of indium, about 35-65 wt % of tin, about 1-10 wt % of silver and about 1-10 wt % of zinc.

Additional contemplated solder compositions are as follows: InSn=52% In (by weight) and 48% Sn (by weight) with a melting point of 118° C.; InAg=97% In (by weight) and 3% Ag (by weight) with a melting point of 143° C.; In=100% indium (by weight) with a melting point of 157° C.; SnAgCu=94.5% tin (by weight), 3.5% silver (by weight) and 2% copper (by weight) with a melting point of 217° C.; SnBi=60% Tin (by weight) and 40% bismuth (by weight) with a melting range of 139-170° C., SnInBi=60% Sn (by weight), 35% In (by weight), and 5% Bi (by weight) with a melting range of 93-140° C., and InSnAgZn 50% In (by weight), 46% Sn (by weight), 2% Ag (by weight) and 2% Sn (by weight) with a melting temperature of 118° C.; and BiSn with 58% Bi, 42% Sn (by weight) with a melting temperature at 138° C. It should be appreciated that other compositions comprising different component percentages can be derived from the subject matter contained herein.

Contemplated solder materials or “fusible materials” may take any form—as will be disclosed herein—including particles, flakes, fibers, nanofibers, tubes, powders, meshes or wires.

As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons tilling the 4f and 5f orbitals surrounding the nucleus of the element, including the lanthanides and the actinides. Preferred metals include indium, silver, copper, aluminum, tin, bismuth, lead, gallium and alloys thereof, silver coated copper, and silver coated aluminum. The term “metal” also includes alloys, metal/metal composites, metal ceramic composites, metal polymer composites, as well as other metal composites. As used herein, the term “compound”) means a substance with constant composition that can be broken down into elements by chemical processes. As used herein, the phrase “metal-based” refers to any coating, film, composition or compound that comprises at least one metal.

In some embodiments, the at least one solder component comprises at least some components or particles having a diameter less than about 40 μm. In other embodiments, the diameter of at least some of those components is less than about 30 μm. In yet other embodiments, the diameter of at least some of those components is less than about 20 μm. It may also be advantageous to have the average component diameter to be less than about 40 μm—meaning that some of the component diameters may be greater than 40 μm and others less than about 40 μm, but the average component diameter is less than about 40 μm.

In some embodiments, it is contemplated that the additions of the at least one high conductivity filler component and the at least one solder material work together or separately to form particle size distributions, such as bimodal particle size distributions or trimodal particle size distributions. In other embodiments, a thermal interface material is formed wherein at least one of the at least one high conductivity filler components comprises particles having a diameter of less than about 100 μm and the mean size of the high conductivity filler component particles is larger than the mean particle size of the solder materials. In yet other embodiments, a thermal interface material is formed wherein at least one of the at least one high conductivity filler components comprises particles having a diameter of less than about 80 μm and the mean size of the high conductivity filler component particles is larger than the mean particle size of the solder materials. In additional embodiments, a thermal interface material is formed wherein at least one of the at least one high conductivity filler components comprises particles having a diameter of less than about 50 μm and the mean size of the high conductivity filler component particles is larger than the mean particle size of the solder materials.

Additionally, contemplated embodiments of thermal interface materials and their methods of production include at least one material modification agent, wherein the at least one material modification agent improves the thermal performance, compatibility, physical quality or a combination thereof of the thermal interface material. As used herein, “material modification agent” includes any compound or composition that can modify the thermal interface material to improve the thermal performance, compatibility and/or physical quality of the resulting material, layer, tape or paste, such as by improving the stability of the polymer matrix, decreasing the viscosity of the material, increasing the surface contact, inhibiting polymerization or crosslinking, improving adhesion or wettability between the thermal interface material and the surrounding surfaces, improving the elasticity of the thermal interface material and resulting layers, tapes or pastes, results in higher thermal filler loading, tailors the curing capability of the thermal interface material for the application or a combination thereof.

The at least one material modification agent may comprise at least one incorporatable organic compound, at least one modified thermal filler profile, at least one stability additives, at least one adhesion promoter, at least one viscosity agent and/or a combination thereof. In some embodiments, the at least one material modification agent may be incorporatable into the thermal interface material, bonded to one of the components of the thermal interface material, or a combination thereof when there is more than one material modification agent.

At least one material modification agent includes any compound or composition that can modify the thermal interface material to improve the thermal performance, compatibility and/or physical quality of the resulting material, layer, tape or paste, such as by improving the stability of the polymer matrix, decreasing the viscosity of the material, increasing the surface contact or wettability between the thermal interface material and the surrounding surfaces, improve the elasticity of the thermal interface material and resulting layers, tapes or pastes, results in higher thermal filler loading, tailors the curing capability of the thermal interface material for the application or a combination thereof. The at least one material modification agent may comprise at least one incorporatable organic compound, at least one modified thermal filler profile, at least one stability additive, at least one viscosity agent and/or a combination thereof.

Contemplated material modification agents include at least one incorporatable organic compound. The term “incorporatable” means that the compound may either be added directly to the thermal interface material as an independent component or may be coupled with another component, such as a monomer, polymer, co-polymer, endcapping or terminal moiety, crosslinking moiety, or any other compound that can be chemically bonded with another compound or moiety. In one contemplated embodiment, an incorporatable organic compound includes an organic flux component that can chemically bond with at least part of the matrix material components and/or matrix material, and in some embodiments, the chemical bonding occurs at a side or terminal location on the molecule. Any suitable organic flux component may be appropriate for this application, for example, a carboxylic acid-containing molecule, such as a dicarboxylic acid or similar organic flux component can be incorporated into the thermal interface material by replacing the polymerizable group with the flux active group, COOH, or adding it into the matrix material or at least one of the matrix material components as a pendant group, or incorporating it into non-polymeric materials such as metal filler or inhibitor. In one embodiment, a portion of the methyl groups in polydimethylsiloxane could be replaced with —COOH groups to make a co-polymer. These side groups could also be added to a microcrystalline wax such as the one used to make a polymer solder hybrid thermal interface material. Organic flux components provide the following specific benefits: a) they bring the flux material into intimate contact with solder powder, fillers, heat spreaders and thermal management components, dies and the like; b) they do not degrade the polymer; c) they increase the stability of the thermal interface materials; d) they allow the fluxes to be activated at the correct temperatures when the thermal interface material is heated for curing; and e) the fluxes do not have an adverse impact on the polymer curing.

Another example of an incorporatable organic compound includes those compounds that are independent of other constituents in the thermal interface material. These compounds may or may not react with constituents of the thermal interface material upon certain applied conditions, such as heat, vibration, light or other stimulating force. For example, in order to make the matrix material of the thermal interface material more elastic while keeping a suitable amount of SiH groups, polyols such as polypropylene glycol, can be used as an incorporatable organic compound. Contemplated polyol compounds include polyalkene glycols, such as polypropylene glycol or polyethylene glycol. Through the addition of a polyol compound, the cured thermal interface material showed more elasticity. It is assumed that the polyol reacts with the SiH group of the siloxane polymer in the presence of a metal catalyst, such as platinum, thus, the incorporatable organic compound becomes part of the crosslinked matrix material. These particular incorporatable organic compounds are important, because materials used in the IC packaging area should possess appropriate mechanical properties in order to mitigate compressive, tensile, and/or shear stresses generated due to GTE mismatch of various components used in the die and the packaging. Typically, an indium-based thermal interface material (TIM) is compliant because of the material's inherent property and relatively thicker BLT. In contrast, other types of solder-based thermal interface materials may result in a joint fracture between the mating surfaces during thermal cycling when BLT, modulus and CTE of the materials are not optimized. One way to solve this problem is to make the material elastic by using an elastomer. In conventional embodiments, an elastomer based on silicone polymer is obtained by incorporating a long linear siloxane polymer, while keeping a lower amount of crosslinkable siloxane starting polymer. In these embodiments, an incorporatable organic compound is utilized to improve elasticity in the polymer matrix and thermal interface material.

In yet another embodiment where incorporatable organic compounds are utilized, stearic or oleic acid can be applied to coat the solder powders in order to both serve as a flux and provide additional lubricity between particles and reduce the viscosity of the highly loaded paste. These organic compounds can also be added as loose powder/liquid, as applicable to the mixture during mixing.

Another contemplated material modification agent includes viscosity modifying components that are designed to reduce the viscosity of the silicone resin in order to allow a larger volume fraction of metal filler than could be accommodated in conventional applications. Examples of contemplated viscosity-modifying components include the use of lower molecular weight polymers and polymers that do not bond to the filler particles until after they are cured.

Another contemplated material modification agent includes at least one modified thermal filler profile. As used herein, a “modified thermal filler profile” means that the thermal fillers incorporated into the thermal interface material are designed in such a way as to optimize the particle size distribution for the highest possible or maximum volume fraction loading. For example, some of the particles may be larger in diameter, while the remaining particles are significantly smaller in diameter. The average diameter may be the same as a particle size profile that contains all medium sized particles, but by making this modification to the particle size distribution, a deep trough between the peaks in the particle size distribution is formed and higher filler loading is achieved than can be achieved by either a monomodal particle size distribution or one where the trough in the particle size distribution is not very deep and the distribution is therefore more uniform. In some embodiments, maximizing the volume fraction loading includes a volume fraction loading of at least 50 volume percent (vol %). In other embodiments, maximizing the volume fraction loading includes a volume fraction loading of at least 60 volume percent (vol %). In yet other embodiments, maximizing the volume fraction loading includes a volume fraction loading of at least 65 volume percent (vol %). And in additional embodiments, maximizing the volume fraction loading includes a volume fraction loading of at least 70 volume percent (vol %).

Another contemplated material modification agent is to increase the concentration of catalyst, crosslinker, and hydride-terminated siloxane in the resin, in order to effect cure to the appropriate extent in the presence of the metal powder. The concentration of the catalyst ranges from 0.01 wt % to 2.00 wt % of the resin total weight, preferably from 0.05 to 0.4%. The concentration of the crosslinker ranges from 0.2 wt % to 10 wt % of the resin total weight, preferably from 1% to 3%. The concentration of hydride-terminated siloxane ranges from 10 wt % to 50 wt % of the resin total weight, preferably from 15 wt % to 35 wt %.

Another contemplated material modification agent is the use of an inhibitor compound to extend the room temperature pot life of the thermal interface material, to increase the elasticity of the matrix material, to inhibit polymerization of the matrix material components or a combination thereof. In some embodiments, contemplated inhibitors comprise a diol component, a triol component, a tetraol component, at least one carboxylic acid, a plurality of small molecules that will coordinate with at least one catalyst or coordination metal (metal catalyst), or a combination thereof. Contemplated inhibitors include acetylenic alcohol (3-hexyne-2,3-diol), acetylenic ketone, other acetylenic organics (10-undecynoic acid). These inhibitors may be added in any suitable amount, including 0.001%-2.0% of the total resin weight.

As used herein, the term “catalyst” means any substance that affects the rate of the chemical reaction by lowering the activation energy for the chemical reaction. In some cases, the catalyst will lower the activation energy of a chemical reaction without itself being consumed or undergoing a chemical change. In some embodiments, contemplated catalysts are metal catalysts, such as coordination metals. Catalysts that include platinum, iron, silver, aluminum, vanadium, tin, palladium, indium and nickel are good examples of metal catalysts. In some embodiments, catalysts may comprise radical initiators, such as AIBN or benzoyl peroxides. In yet other embodiments, contemplated catalysts may be any component or molecule that is readily accepted as and/or fits within the stated definition of a catalyst.

In some embodiments, contemplated material modification agents comprise adhesion promoters that enhance the attraction and/or bonding between the silicon-based material or silicone resin and the metalized and non-metalized silicon surface. Contemplated adhesion promoters may comprise functional groups, such as epoxy, silane, vinylsilane, methacrylate, silanol, thiol, carboxylic acid, amine, hydroxyl, alkoxide, epoxy-functionalized siloxane materials, such as an epoxy-functionalized siloxane-siloxane copolymer or a combination thereof. In some embodiments, contemplated adhesion promoters comprise hydridosilane, alkoxylsilane, silanol, acrylate and cyano, which may be chemically bonded to siloxane. Contemplated adhesion promoters should be miscible with the at least one matrix material and/or thermal interface material. In some embodiments, these material modification agents don't decrease shelf life, help bond the metal and solder filler to the metalized and non-metalized surface, increase thermal conductivity and improve resistance to thermal cycling. Adhesion may also be increased by decreasing or modifying the amount of curing inhibitor. An example of this type of material modification agent is described in Example 11.

In some embodiments, there may be at least one additional material incorporated into contemplated thermal interface materials. Contemplated additional materials may comprise metal and metal-based materials, such as those manufactured by Honeywell International Inc., such as solders, connected to heat spreaders composed of Ni, Cu, Al, AlSiC, copper composites, CuW, diamond, graphite, SiC, carbon composites and diamond composites which are classified as heat spreaders or those materials that work to dissipate heat.

In some embodiments, at least part of the at least one material modification agent may be directly applied to another material or component prior to incorporation into the thermal interface material, including the at least one high conductivity filler and/or the at least one solder material. In one such example, at least one of the at least one high conductivity filler and/or the at least one solder material may be coated with a carboxylic acid-containing molecule prior to incorporation into the thermal interface material.

Additional components, such as a plurality of low modulus metal-coated polymer spheres or microspheres may be added to the thermal interface material to decrease the bulk elastic modulus of the TIM. An additional component may also be added to the TIM to promote wetting to the die and/or heat spreader surface. These additions are contemplated to be silicide formers, or elements that have a higher affinity for oxygen or nitrogen than does silicon. The additions can be one element that satisfies all requirements, or multiple elements each of which has at least one advantage. Additionally, alloying elements may be added which increase the solubility of the dopant elements in the at least one solder material or component.

Vapor grown carbon fibers and other fillers, such as substantially spherical filler particles may be incorporated. Additionally, substantially spherical shapes or the like will also provide some control of the thickness during package assembly and thermal curing. Dispersion of filler particles can be facilitated by the addition of functional organometallic coupling agents or wetting agents, such as organosilane, organotitanate, organozirconium, etc. Typical particle sizes useful for fillers in the resin material may be in the range of about 1-20 μm with a maximum of about 250 μm.

These compounds may comprise at least some of the following: at least one silicone compound in 1 to 20 weight percent, organotitanate in 0-10 weight percent, at least one solder material in 5 to 95 weight percent, at least one high conductivity filler in 0-90 weight percent. These compounds may include one or more of the optional additions, e.g., wettability enhancer. The amounts of such additions may vary but, generally, they may be usefully present in the following approximate amounts (in wt. %): filler up to 95% of total (filler plus resins); wettability enhancer 0.1 to 5% (of total), and adhesion promoters 0.01 to 1% (of total). It should be noted that the addition of at least about 0.5% carbon fiber significantly increases thermal conductivity. These compositions are described in US Issued Patent 6706219, U.S. application Ser. No. 10/775,989 filed on Feb. 9, 2004 and PCT Serial No.: PCT/US02/14613, which are all commonly owned and incorporated herein in their entirety by reference.

Thermal interface materials disclosed herein have several advantages directly related to use and component engineering, such as: a) the interface material/polymer solder material can be used to fill small gaps on the order of 0.2 millimeters or smaller, b) the interface material/polymer solder material can efficiently dissipate heat in those very small gaps as well as larger gaps, unlike most conventional solder materials, and c) the interface material/polymer solder material can be easily incorporated into micro components, components used for satellites, and small electronic components. The solder-based interface materials also have several advantages directly related to use and component engineering, such as: a) high bulk thermal conductivity, b) metallic bonds may be formed at the joining surfaces, lowering contact resistance c) the interface solder material can be easily incorporated into micro components, components used for satellites, and small electronic components.

The contemplated thermal interface component can be provided as a dispensable paste to be applied by dispensing methods (such as screen printing, stencil printing, or automated dispensing) and then cured as desired. It can also be provided as a highly compliant, cured, elastomer film or sheet for pre-application on interface surfaces, such as heat sinks. It can further be provided and produced as a soft gel or liquid that can be applied to surfaces by any suitable dispensing method, such as screen-printing or ink jet printing. Even further, the thermal interface component can be provided as a tape that can be applied directly to interface surfaces or electronic components.

Thermal interface materials and related layers can be laid down in any suitable thickness, depending on the needs of the electronic component, and the vendor as long as the thermal interface component is able to sufficiently perform the task of dissipating some or all of the heat generated from the electronic component to which it is attached. Contemplated thicknesses comprise thicknesses in the range of about 0.050-0.100 mm. In some embodiments, contemplated thicknesses of thermal interface materials are within the range of about 0.030-0.150 mm. In other embodiments, contemplated thicknesses of thermal interface materials are within the range of about 0.010-0.250 mm.

When using a metallic thermal interface material, like solder, which has a high elastic modulus compared to most polymer systems, it may be necessary to reduce the coefficient of thermal expansion mismatch generated mechanical stresses transferred to the semiconductor die in order to prevent cracking of the die. This stress transfer can be minimized by increasing the bondline thickness of the metallic thermal interface material or reducing the coefficient of thermal expansion of the heat spreader. Increasing the bondline thickness generally increases the thermal resistance of the interface, but including a high conductivity mesh as part of the thicker TIM as disclosed in this application can minimize this increase and even result in lower thermal resistance than for the TIM alone. Examples of lower coefficient of thermal expansion (CTE) materials for heat spreaders are AlSiG, CuSiC, copper-graphite composites, carbon-carbon composites, diamond, CuMou laminates, etc.

As mentioned, the at least one thermal interface material may be coupled with a metal-based coating, layer and/or film. In contemplated embodiments, metal-based coating layers may comprise any suitable metal that can be coupled to the surface of the thermal interface material or surface/support material in a layer. In some embodiments, the metal-based coating layer comprises indium, such as from indium metal, In33Bi, In33BiGd and In3Ag and can also include nickel and/or gold. These metal-based coating layers are generally laid down on a surface by any method capable of producing a uniform layer with a minimum of pores or voids and can further lay down the layer with a relatively high deposition rate. Many suitable methods and apparatus are available to lay down layers or ultra thin layers of this type, such as spot plating or pulsed plating. Pulsed plating (which is intermittent plating as opposed to direct current plating) can lay down layers that are free or virtually free of pores and/or voids.

In some contemplated embodiments, thermal interface material can be directly deposited onto at least one of the sides of the heat spreader component, such as the bottom side, the top side or both. In some contemplated embodiments, the thermal interface material is silk screened, stencil printed, screen printed or dispensed directly onto the heat spreader or heat generating device by methods such as jetting, thermal spray, liquid molding or powder spray, and also the common method of paste dispensing via a syringe tipped with a needle or a nozzle. In yet other contemplated embodiments, a film of thermal interface material is deposited and combined with other methods of building adequate thermal interface material thickness, including direct attachment of a preform or silk screening of a thermal interface material paste.

Methods of forming layered thermal interface materials and thermal transfer materials include: a) providing a heat spreader component, wherein the heat spreader component comprises a top surface, a bottom surface and at least one heat spreader material; b) providing at least one thermal interface material, such as those described herein, wherein the thermal interface material is directly deposited onto the bottom surface of the heat spreader component; c) depositing, applying or coating a metal-based coating, film or layer on at least part of the bottom surface of the heat spreader component; d) depositing, applying or coating the at least one thermal interface material onto at least part of at least one of the surfaces of the heat spreader component or heat generating device, and e) bringing the bottom of the heat spreader component with the thermal interface material into contact with the heat generating device, generally a semiconductor die.

Once deposited, applied or coated, the thermal interface material layer comprises a portion that is directly coupled to the heat spreader material and a portion that is exposed to the atmosphere, or covered by a protective layer or film that can be removed just prior to installation of the heat spreader component. Additional methods include providing at least one adhesive component and coupling the at least one adhesive component to at least part of at least one of the surfaces of the at least one heat spreader material and/or to or in at least part of the thermal interface material. At least one additional layer, including a substrate layer, can be coupled to the layered interface material.

As described herein, optimal interface materials and/or components possessing a high thermal conductivity and a high mechanical compliance, e.g. will yield elastically or plastically on a local level when force is applied. In some embodiments, optimal interface materials and/or components will possess a high thermal conductivity and good gap-filling properties, High thermal conductivity reduces the first term of Equation 1 while high mechanical compliance reduces the second term. The layered interface materials and the individual components of the layered interface materials described herein accomplish these goals. When properly produced, the thermal interface component described herein will span the distance between the mating surfaces of the heat producing device and the heat spreader component thereby allowing a continuous high conductivity path from one surface to the other surface. Suitable thermal interface components comprise those materials that can conform to the mating surfaces, possess a low bulk thermal resistance and possess a low contact resistance.

Pre-attached/pre-assembled thermal solutions and/or IC (interconnect) packages comprise one or more components of the thermal interface materials described herein and at least one adhesive component. These thermal interface materials exhibit low thermal resistance for a wide variety of interface conditions and demands. As used herein, the term “adhesive component” means any substance, inorganic or organic, natural or synthetic, that is capable of bonding other substances together by surface attachment. In some embodiments, the adhesive component may be added to or mixed with the thermal interface material, may actually be the thermal interface material or may be coupled, but not mixed, with the thermal interface material. Examples of some contemplated adhesive components comprise double-sided tape from SONY, such as SONY T4411, 3M F9460PC or SONY T4100D203. In other embodiments, the adhesive may serve the additional function of attaching the heat spreading component to the package substrate independent of the thermal interface material.

Contemplated thermal interface materials, along with layered thermal interface materials and components may then be applied to a substrate, another surface, or another layered material. The electronic component may comprise, for example, a thermal interface material, a substrate layer and an additional layer. Substrates contemplated herein may comprise any desirable substantially solid material. Particularly desirable substrate layers would comprise films, glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe or heat spreader, a copper surface such as found in a circuit board or package interconnect trace, a via-wall or stiffener interface (“copper” includes considerations of bare copper and it's oxides), a polymer-based packaging or board interface such as found in a polyimide-based flex package, lead or other metal alloy solder ball surface, glass and polymers such as polyimide. The “substrate” may even be defined as another polymer material when considering cohesive interfaces. In more preferred embodiments, the substrate comprises a material common in the packaging and circuit board industries such as silicon, copper, glass, and another polymer.

Additional layers of material may be coupled to the thermal interface materials or layered interface materials in order to continue building a layered component or printed circuit board. It is contemplated that the additional layers will comprise materials similar to those already described herein, including metals, metal alloys, composite materials, polymers, monomers, organic compounds, inorganic compounds, organometallic compounds, resins, adhesives and optical wave-guide materials.

Several methods and many thermal interface materials can be utilized to form these pre-attached/pre-assembled thermal solution components. A method for forming the thermal solution/package and/or IC package includes: a) providing the thermal interface material or layered interface material described herein; b) providing at least one surface or substrate; c) coupling the at least one thermal interface material and/or layered interface material to form an adhesive unit; d) coupling the adhesive unit to the at least one surface or substrate to form a thermal package; e) optionally coupling an additional layer or component to the thermal package.

Applications of the contemplated thermal solutions, IC packages, thermal interface components, layered interface materials and heat spreader components described herein comprise incorporating the materials and/or components into another layered material, an electronic component or a finished electronic product. Electronic components, as contemplated herein, are generally thought to comprise any layered component that can be utilized in an electronic-based product. Contemplated electronic components comprise circuit boards, chip packaging, separator sheets, dielectric components of circuit boards, printed-wiring boards, and other components of circuit boards, such as capacitors, inductors, and resistors.

### EXAMPLES

The following key applies to abbreviations throughout the examples.
DMS-V22: Vinyl Terminated PolyDimethylsiloxane, MW=9400
DMS-V31: Vinyl Terminated PolyDimethylsiloxane, MW=28000
DMS-V46: Vinyl Terminated PolyDimethylsiloxane, MW=117000
DMS-H11: Hydride Terminated PolyDimethylsiloxane, MW=1000-1100
DMS-H21: Hydride Terminated PolyDimethylsiloxane, MW=6000
HMS-501: MethylHydrosiloxane—Dimethylsiloxane Copolymer, Trimethylsiloxy terminated, cross linker
SIP 6829.2: Platinum Carbonyl Cyclovinylmethylsiloxane complex, catalyst

### Example 1

### Effect of Inhibitor with and Without Silver

A baseline material comprising 47.4 gm DMS-V22, 26.6 gm DMS-V46, 25.7 gm DMS-H21, 1.8 gm HMS-501 and 0.20 gm SIP6829.2 was prepared. To this baseline resin, two levels of 3-hexyne-2,5-diol (the inhibitor) were added. Including the baseline resins, there were 3 resin formulations with 0%, 0.10% and 0.50 wt. % 3-hexyne-2,5-diol.

The shelf life of both the resins and the pastes made from them using 1 part of the resin mixed with 2 parts of Ag powder (Metalor K00082P) by weight were evaluated. The compositions of the six samples, three with Ag powder and three without, are listed below.

| Component | 40846-12 | 40846-12-2A | 40846-12-3A | 40846-12-1 | 40846-12-2B | 40846-12-3B |
|---|---|---|---|---|---|---|
| Resin Composition | Wt % | Wt % | Wt % | Wt % | Wt % | Wt % |
| Gelest DMS-V22 | 46.5% | 46.4% | 46.2% | 46.5% | 46.4% | 46.2% |
| Gelest DMS-V46 | 26.2% | 26.2% | 26.1% | 26.2% | 26.2% | 26.1% |
| Gelest DMS-H21 | 25.3% | 25.3% | 25.2% | 25.3% | 25.3% | 25.2% |
| Gelest HMS-501 | 1.8% | 1.8% | 1.8% | 1.8% | 1.8% | 1.8% |
| Gelest SIP | 0.2% | 0.2% | 0.2% | 0.2% | 0.2% | 0.2% |
| 6829.2 | | | | | | |
| Inhibitor 3- | 0.00% | 0.10% | 0.50% | 0.00% | 0.10% | 0.50% |
| hexyne-2,5-diol | | | | | | |
| Resin in Mix | 100% | 100% | 100% | 33.33% | 33.33% | 33.33% |
| Metalor K0082-P | 0% | 0% | 0% | 66.67% | 66.67% | 66.67% |
| in Mix | | | | | | |
| 150 C./30 min cure | hard gel | sticky gel | viscous liquid | rubbery gel | rubbery gel | rubbery gel |
| Gel Time at RT | 3 hr | >26 days | >26 days | 7 hr | >26 days | >26 days |

It can be seen that addition of as low as 0.10% 3-hexyne-2,5-diol improved the shelf life of both the resin and the resin/Ag paste to more than 26 days at room temperature. At the same time, the paste can still can be cured to a rubbery gel at normal cure condition of 150° C. for 30 minutes. It demonstrates that the 3-hexyne-2,5-diol improves shelf life of the paste significantly, but does not hinder curing of the paste at 150° C.

### Example 2

### The Effect of Inhibitor in the Presence of Silver and Solder

Powders of Metator Ag and Bi42Sn solder were mixed in 1:2 weight ratio. The powder mixture was then blended with separately mixed resin stock.

| Component | 40846-24A | 40846-25A |
|---|---|---|
| Resin Composition | Wt % | Wt % |
| Gelest DMS-V22 | 55.6% | 55.6% |
| Gelest DMS-V31 | 11.9% | 11.9% |
| Gelest DMS-H21 | 30.8% | 30.8% |
| Gelest HMS-501 | 1.5% | 1.5% |
| Gelest SIP 6829.2 | 0.2% | 0.2% |
| Inhibitor 3-hexyne-2,5-diol | 0.0% | 0.014% |
| Resin in Mix | 6.25% | 4.55% |
| Metalor K00082P Ag powder in Mix | 31.25% | 31.82% |
| Indium Corp type 6 Bi42Sn powder in Mix | 62.5% | 63.63% |
| 150 C./30 min cure | Rubbery gel | Rubbery gel |
| Gel Time at RT | 10 hr | 5 days |

Addition of small amount of 3-hexyne-2,5-diol as low as 0.014 wt % with respect to the weight of the resin increases the shelf life at room temperature to 5 days from 10 hours, yet the resin is still cured to rubbery state at 150° C.

### Example 3

### Effect of Decreasing the Crosslinker to Increase Elasticity of the Thermal Interface Material

One of the goals for polymer design is to increase elasticity of the cured polymer, which was done by changing the linear chain length of the cured polymer. The amount of hydride terminated polydimethylsiloxane and the crosslinker were varied while keeping the ratio of high to low molecular weight vinyl terminated polydimethylsiloxane constant. The example formulations and measured elongations are in the table below:

| | Sun-11 | | Sun-18 | | Sun-19 | | Sun-20 | |
|---|---|---|---|---|---|---|---|---|
| DMS-V22 | 16 | g | 16 | g | 16 | g | 16 | g |
| DMS-V46 | 9 | g | 9 | g | 9 | g | 9 | g |
| DMS-H21 | | | 1.0 | g | 3.6 | g | 8.69 | g |
| HMS-501 | 0.57 | g | 0.52 | g | 0.373 | g | 0.1 | g |
| **SIP6829.2 | 90 | mg | 90 | mg | 90 | mg | 90 | mg |

| | | | | |
|---|---|---|---|---|
| Elongation % | 20 | 20 | 26 | 400 |

**The Pt catalyst was added by dissolving 433 mg of SIP6829.2 into 25 g of DMSV22 and adding 90 mg of this solution containing 0.04 mg of Pt to the mixture.

The low level of crosslinker (HMS501) and the high level of the hydride terminated dimethylsiloxane (HMS-501) are critical in achieving a high elongation of the cured polymer as demonstrated by the 400% elongation of the Sun-20 formulation.

### Example 4

### The Effect of Additives on Curing and Pot Life of Resin

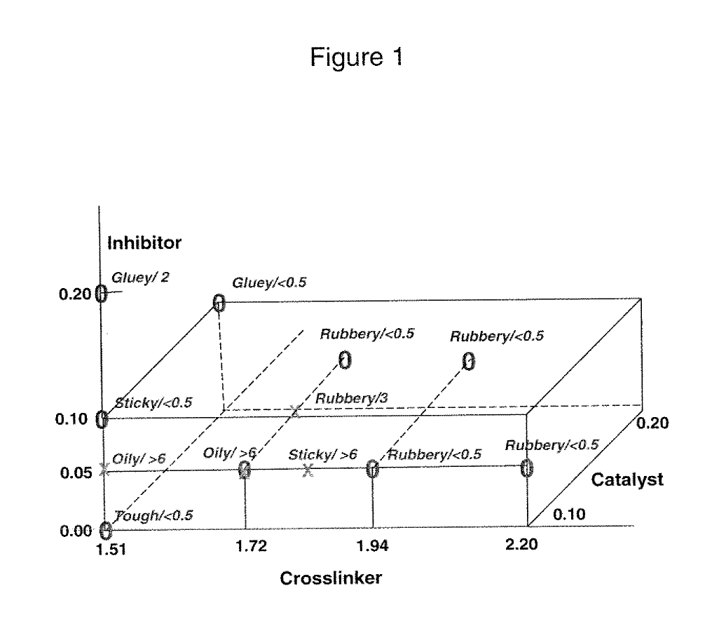

A base resin was prepared by mixing 42.0 gm DMS-V22, 23.0 gm DMS-V31 and 26.0 gm DMS-H21. To this base resin, three additives with various amounts were added to give the final additive concentrations as indicated below.
1) HMS-501 (Crosslinker): 1.51 wt %, 1.72 wt %, 1.94 wt % and 2.20 wt %.
2) SIP6829.2 (Catalyst): 0.10 wt % and 0.20 wt %
3) 3-hexyne-2,5-diol (inhibitor): 0%, 0.05 wt %, 0.10 wt % and 0.20 wt %
   The resin was cured at 15° C. for 30 minutes and checked for gel rigidity. The physical state of the gel is classified as: (a) oily, (b) sticky, (c) gluey, (d) rubbery and (e) tough in the order of increasing rigidity. The resin was also left at room temperature and the appropriate gel time (pot life) was recorded. The results were depicted in the following graph where the gel physical state and pot life (in days) were entered along with the specific additive composition. As shown in FIG. 1, the toughness of the gel increases with increasing amount of cross-linker and catalyst and decreases with increasing amount of inhibitor. On the other hand, the pot life of the resin decreases with increasing amounts of catalyst and cross-linker and increases with increasing amount of inhibitor.

### Example 5

### Addition of Polyols as the Material Modification Agent

To make the polymer matrix of the thermal interface material more elastic without increasing the amount of SiH groups, polyols such as polypropylene glycol were added. Through the addition of a polyol compound, the cured thermal interface material showed more elasticity. This method is also useful to modify the adhesion strength of the cured polymer materials to substrates such as silicon wafers. Another advantage with this method is that polyols can be used as polymerizable additive. When polyols such as polypropylene glycol (PrPEG) is added, a degree of the polymer curing was increased and the cured materials became more elastic.

Examples of the formulations: 40306-26T and 40306-26Q (Sun42A is control) are shown below:

| | Sun-42A | | 40306-26T | | 40306-26Q | | Sun-39AP | | Sun-40AP-I | |
|---|---|---|---|---|---|---|---|---|---|---|
| DMS-V22 | 12.4 | g | 12.4 | g | 12.4 | g | 10.5 | g | 10.5 | g |
| DMS-H21 | 5.0 | g | 5.0 | g | 5.0 | g | 6.5 | g | 6.5 | g |
| DMS-V31 | 0 | | 0 | | 0 | | 5.75 | g | 5.75 | g |
| HMS-501 | 0.26 | g | 0.26 | g | 0.26 | g | 0.344 | g | 0.344 | g |
| SIP6829.2 | 0.0191 | g | 0.0191 | g | 0.0191 | g | 0.025 | g | 0.025 | g |
| 3-hexyne-2,3-diol | 0 | | 0 | | 0.0124 | g | 0 | | 0.0028 | |
| PrPEG | 0 | | 0.254 | g | 0.380 | g | 0.068 | | 0.068 | |
| Metalor silver | 34 | g | 34 | g | 34 | g | 46 | g | 46 | g |

| | | | | | |
|---|---|---|---|---|---|
| After cured | 95% cured | Rubbery | Rubbery | Rubbery | Rubbery |

### Example 6

### Particle Size Distribution of Metal Fillers

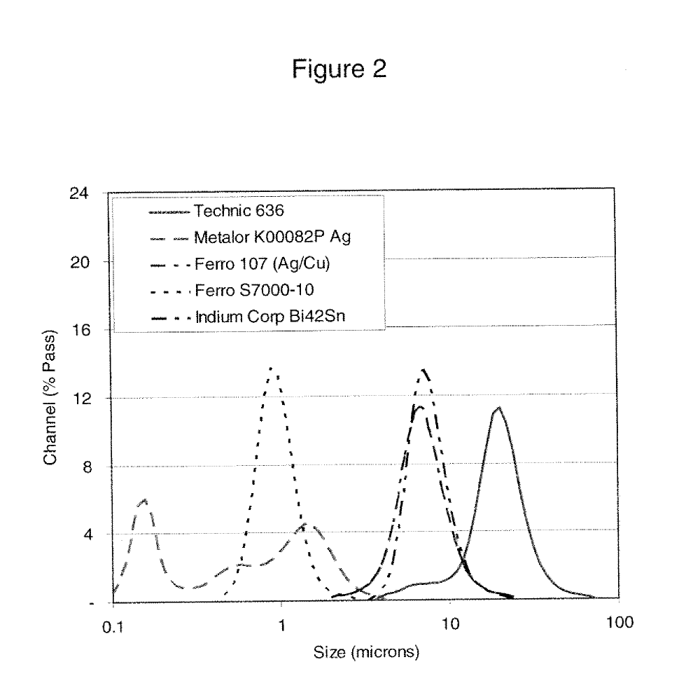

The effect of the filler particle size distribution on the maximum filler loading and thermal performance was examined by using mixtures of fillers having their own unique/characteristic particle size distributions. The particle size distributions for the different powders were measured using a Microtrac X100 particle size analyzer and are shown in FIG. 2. The mean particle diameters are:

| | |
|---|---|
| Technic 636 | 19.2 μm |
| Metalor K00082P | 0.86 μm |
| Ferro 107 | 9.48 μm |
| Ferro S7000-10 | 0.98 μm |
| Indium Bi42Sn | 7.81 μm |

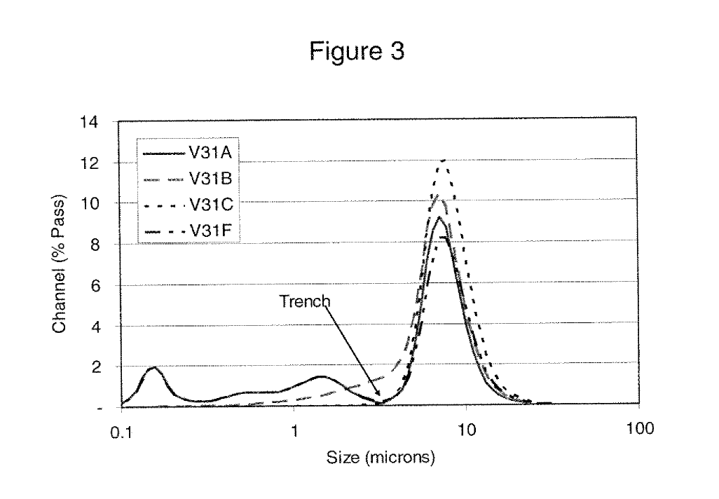

Thermal interface materials were made using mixtures of these powders with the overall compositions in the table below. Samples were prepared by weighing and mixing a large batch of the liquid components in one container using a spatula. The powders were then weighed and also mixed in a separate container using a spatula. The appropriate weight of the mixed liquid was then added to the powder mixture and stirred with the spatula to obtain a paste. The distributions for the powder mixtures used in these thermal interface materials (V31A, V31B, V31E, and V31F) were calculated from the distributions of the individual powders and are displayed in the graph below. The thermal performance of these samples was measured using the cut-bar method as described in ASTM D5470 using precision ground Ni plated Cu blocks. The TIM sample is spread between the blocks along with a pair of parallelly placed 0.0018″ diameter chromel wires to control the bond line thickness. The assembly is then placed in a fixture to apply a pressure of 30 psi to the joint while it is cured at 150° C. in an oven for a total of 35 minutes, five minutes of which are consumed by heat up of the blocks and fixture. Representative samples are shown in the table below and in FIG. 3.

| | V31A | V31B | V31C | V31F |
|---|---|---|---|---|
| Component | Wt % | Wt % | Wt % | Wt % |
| Gelest DMS-V22 | 2.05% | 2.45% | 3.11% | 2.10% |
| Gelest DMS-V31 | 1.12% | 1.34% | 1.70% | 1.15% |
| Gelest DMS-H21 | 1.27% | 1.52% | 1.92% | 1.30% |
| Gelest HMS-501 | 0.069% | 0.082% | 0.104% | 0.070% |
| Gelest SIP 6829.2 | 0.0049% | 0.0058% | 0.0074% | 0.0050% |
| Metalor K00082P Ag powder | 34.92% | | | 34.56% |
| Ferro SFG-ED Ag powder | | 34.62% | | |
| Ferro AgCu107 powder | 0.00% | | 30.93% | 18.65% |
| Indium Corp type 6 Bi42Sn | 60.55% | 59.98% | 62.24% | 42.16% |
| powder | | | | |
| Total Filler Loading (vol %) | 70.37% | 66.33% | 61.73% | 69.62% |
| Thermal Impedance (° C.-cm²/W) | 0.086 | 0.086 | 0.538 | 0.071 |
| Thermal Conductivity (W/m-K) | 5.3 | 8.8 | 2.1 | 6.0 |
| Bond Line Thickness (μm) | 45.9 | 75.3 | 110.5 | 42.5 |

The trimodal filler particle size distribution of samples V31A and V31F had the highest filler loading and resulted in a TIM that could be compressed to the desired bond line thickness at a typical cure pressure of 30 psi. The very narrow particle size distribution of sample V31C resulted in low filler loading, a very large bond line thickness, and very poor thermal performance. The particle size distribution of sample V31B was similar to V31C, but had a long tail to the small sizes that resulted in slightly better loading, bond line, and thermal performance. Samples V31A and V31F had nearly identical particle size distributions, but the larger particles in sample V31F were a mixture of Bi42Sn solder powder and Ag coated Cu filler rather than only Bi42Sn solder powder, which resulted in better thermal performance.

### Example 7

### Effect of Stearic Acid Addition

Stearic acid (J. T. Baker, triple pressed) was added to the TIM as a flux to remove the oxides from the solders the spreader, die back, and the fillers, therefore reducing the contact resistance of the joint. The stearic acid was either added by mixing the stearic acid powder with the metal powders prior to addition of the polymer components (50A, 50E, and 50H) or by coating the Bi42Sn solder with stearic acid. The coating was done by dissolving the stearic acid in acetone at 60° C., adding the Bi42Sn powder while stirring, and then evaporating off the acetone. The stearic acid can also be melted first, and then was added into acetone at 60° C. to make miscible solution while vigorously stirring, followed by the same procedure as above. In both cases the total amount of stearic acid was 0.6 wt % of the Bi42Sn powder. All three samples had high filler loading of 69-72 vol %, bondline thicknesses near 0.050 mm, and thermal impedance of less than 0.05° C.-cm²/W as measured via the cut-bar methodology. The thermal impedance of sample 50H was measured by the flash diffusivity method as described in the next example.

| Component | 50A | 50B | 50C | 50D | 50E | 50F | 50G | 50H |
|---|---|---|---|---|---|---|---|---|
| Gelest DMS-V22 | 2.48% | 2.24% | 2.11% | 2.16% | 2.63% | 2.4589% | 2.4576% | 2.24% |
| Gelest DMS-V31 | 0.53% | 0.48% | 0.45% | 0.46% | 0.56% | 0.52% | 0.52% | 0.48% |
| Gelest DMS-H21 | 1.37% | 1.24% | 1.17% | 1.19% | 1.46% | 1.36% | 1.36% | 1.24% |
| Gelest HMS-501 | 0.066% | 0.060% | 0.057% | 0.058% | 0.071% | 0.066% | 0.066% | 0.060% |
| Gelest SIP 6829.2 | 0.0067% | 0.0060% | 0.0057% | 0.0058% | 0.0071% | 0.0066% | 0.0066% | 0.0060% |
| Stearic Acid | 0.25% | | | | 0.25% | | | 0.25% |
| Technic 636 Ag powder | | | | | | | | 6.13% |
| Metalor K00082P Ag powder | 34.50% | 34.66% | | 17.18% | | 17.22% | 13.51% | 34.30% |
| Ferro AgCu107 powder | 18.64% | 18.74% | 18.71% | 18.53% | 18.63% | 4.90% | 31.53% | 13.23% |
| Ferro S7000-10 Ag powder | | | 34.69% | 17.79% | 34.36% | 32.17% | 33.43% | |
| Indium Corp type 6 Bi42Sn | 42.17% | | | | 42.03% | | | 42.08% |
| powder | | | | | | | | |
| Indium Corp type 6 Bi42Sn | | 42.58% | 42.81% | 42.62% | | 41.30% | 17.12% | |
| powder | | | | | | | | |
| coated with 0.6 wt % stearic acid | | | | | | | | |
| Metals Loading (vol %) | 69.0% | 71.1% | 72.2% | 70.6% | 66.4% | 67.40% | 68% | 69.7% |
| Thermal Impedance (° C.-cm²/W) | 0.043 | 0.046 | 0.047 | 0.049 | 0.057 | | | 0.019 |
| Thermal Conductivity (W/m-K) | 11.0 | 12.1 | 10.1 | 13.8 | 9.4 | | | 26.1 |
| Bond Line Thickness (μm) | 47.4 | 55.5 | 47.4 | 67.8 | 53.4 | | | 49.5 |

### Example 8

### Flash Diffusivity Thermal Test Methodology

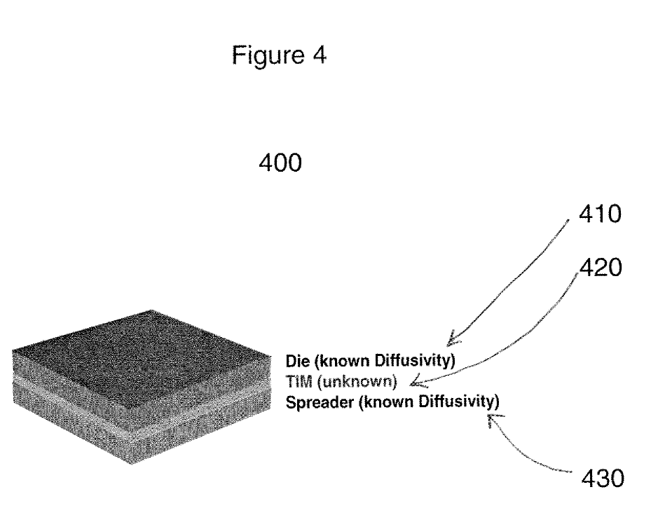

Samples 50A, 50B, 50C, and 50D from the previous example were used to qualify flash diffusivity to measure the thermal performance of the TIMs. This method has the advantages of (1) mimicking a real package by being able to test between a Si die and a Cu spreader, and (2) being faster for both sample preparation and testing. In this method a three-layer sandwich 400, shown in FIG. 4, composed of a Cu heat spreader 410 plated with Ni and Au, the thermal interface material 420, and a Si die 430 that had been sputtered with Ti, Ni, and finally Au is created by stacking the layers and curing the stack in a fixture at 30 psi applied pressure. The thermal diffusivity of the sample was measured on a Netzsch LFA-447 NanoFash unit and the thermal diffusivity of the TIM was deconvoluted from the overall thermal diffusivity using the “three-layer plus heat loss” algorithm in the Netzsch Proteus LFA Analysis software.

Thermal diffusivity, thermal conductivity, and thermal impedance of the TIM are related by the equations listed below.

Thermal Diffusivity: α=λ/ρ*Cp[cm²/s]

Thermal Conductivity: λ=α*ρ*Cp[W/(cm-° C.)]

Thermal Impedance, TI=BLT/Conductivity[cm²-° C./W]

Thermal diffusivity and conductivity are bulk material properties that are independent of the BLT, while the thermal impedance depends on BLT and is thus directly relevant to TIM performance interpretation and use in a real application.

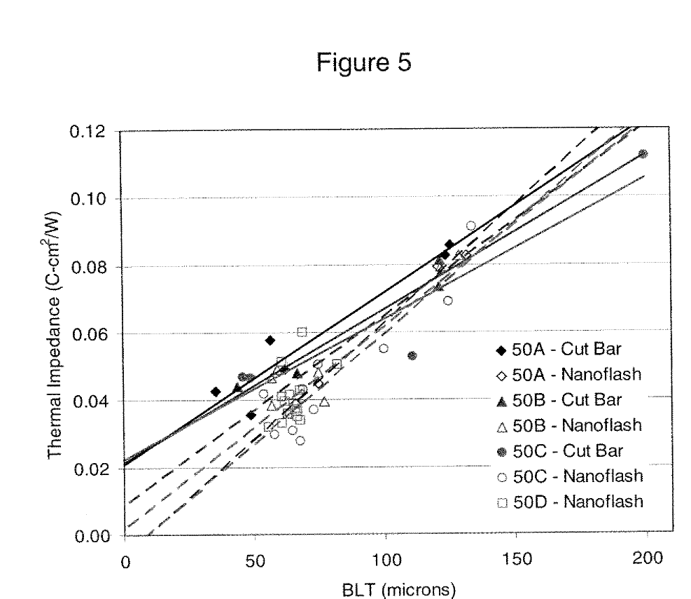

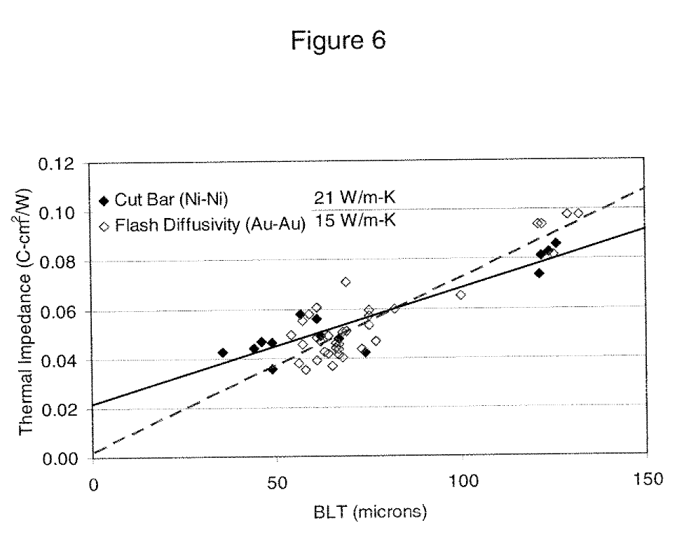

The thermal impedance of these three samples using the two different methods (cut-bar and flash diffusivity) are plotted in FIG. 5 along with linear trend lines for each. It is readily seen that the two methods give very similar results, although slope of the trend line is steeper for the Flash Diffusivity method and the predicted contact resistance (intercept of the trend line with the y-axis) is lower and in some cases even negative. The results of the two different methods are consolidated in FIG. 6, where it is very clear that the two methods give very similar results in the 50-80 μm thick bond line range which is where these TIMs are expected to be used most often. The difference in the slopes is due to differences at thicker bond lines.

### Example 9

### Pot Life of the TIM

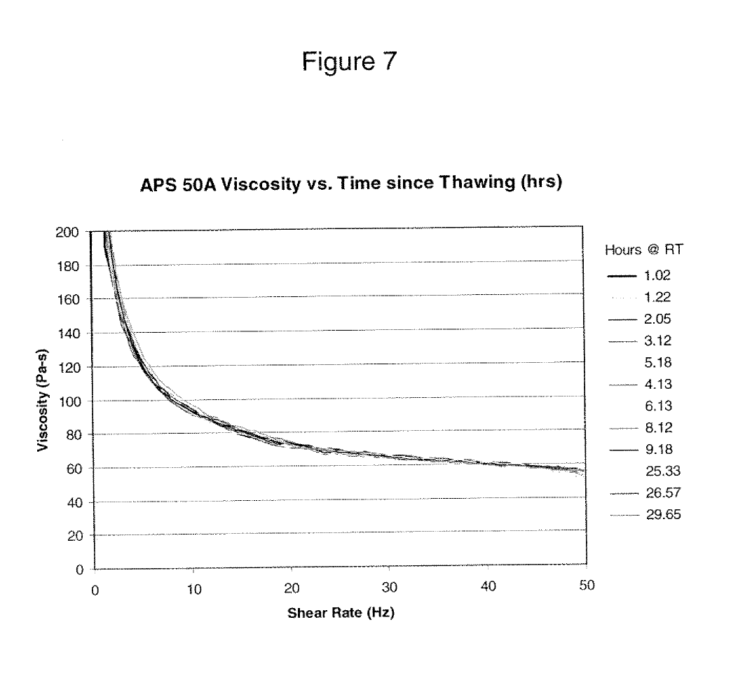

The pot life of sample 50A was evaluated by measuring the viscosity of the TIM paste as a function of shear rate. The viscosity was measured after different thaw times on a Haake RT20 Rotovisco system with cone and plate geometry and a 0.050 mm gap. FIG. 7 shows that the viscosity of the 50A formulation does not change during room temperature (nominally 21° C.) storage of nearly 30 hrs. The thermal performance of cured samples of the 50A material was measured via flash diffusivity after the viscosity study was completed and the thermal impedance was 0.015° C.-cm²/W which compares very favorably with the value of 0.019° C.-cm²/W observed after 30 minutes of thawing.

### Example 10

### Reliability Testing

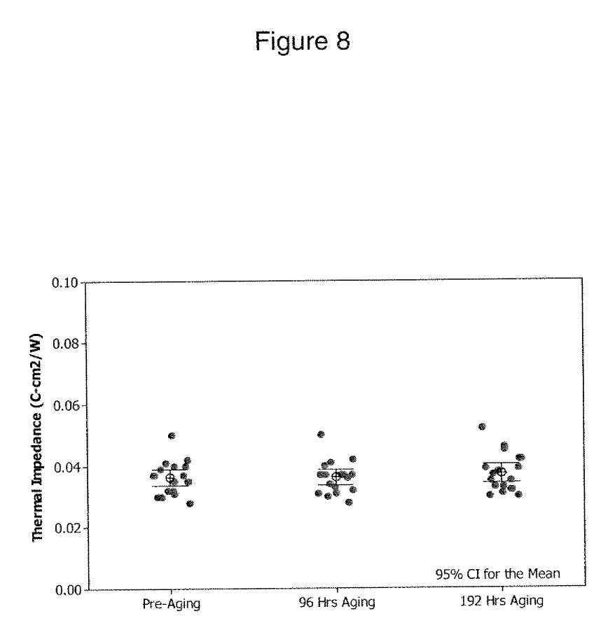

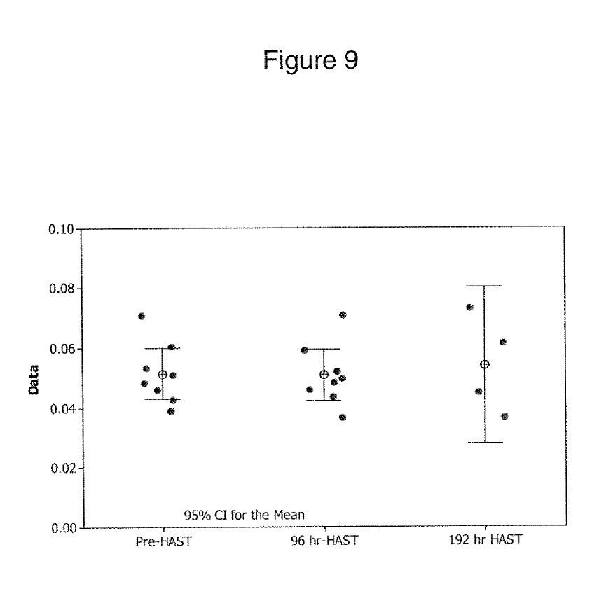

The reliability of the 50A material was evaluated under conditions of both high temperature aging and highly accelerated stress testing (HAST) using flash diffusivity samples. The high temperature aging was carried out at 150° C. for four and eight days while HAST was done at 130° C., 85% relative humidity, and 15 psi gauge pressure for four and eight days. FIGS. 8 and 9 show that the 50A formulation does not degrade significantly during either high temperature aging or highly accelerated stress testing (HAST). Only four of the eight samples were tested for 192 hrs in HAST which is why the confidence interval (CI) increases dramatically for that test at 192 hrs.

### Example 11

### Adhesion Promoter Material Modification Agent

Thermal interface materials comprising adhesion promoter material modification agents were developed and tested for reliability and adhesion. Two epoxy-siloxane materials were used for this Example to test their adhesion with non-metalized silicon. The first material was modified with epoxypropoxypropyl-terminated polydimethylsiloxane (CAS104780-61-2) (GELEST DMS-E11) and the second material was modified with (8-10% epoxycyclohexyethyl)methylsiloxane-dimethylsiloxane copolymer (CAS 67762-95-2) (GELEST ECMS-924).

The materials were tested for break strength between the material and the non-metalized silicon, gel rubber elasticity and shelf life at −20C.

| Formulation lot # | Load to | | | |
|---|---|---|---|---|
| V50 + Adhesion | break | | | |
| Promotor + metals | sample | Load/cm² | Additive A | Additive B |
| w/0.3% stearic acid | grams | g/cm² | DMS-E11 | ECMS-924 |
| 40850-14-1A | 50 | 20 | 1% | — |
| 40850-14-2A | 100 | 33 | 5% | — |
| 40850-14-3A | 300 | 102 | — | 1% |
| 40850-14-4A | 500 | 166 | — | 5% |

1-5 weight percent of epoxycyclohexyethyl)methylsiloxane-dimethylsiloxane copolymer (CAS 67762-95-2) with respect to the weight of the resin increases the adhesion strength of the material to 100-160 g/cm2. All tested materials had the consistency of rubbery gels and they are still “fluidy” after 3 days at −20C.

Thus, specific embodiments and applications of thermal interface materials, methods of production and uses thereof have been disclosed. It should be apparent, however, to those skilled in the art that many more modifications besides those already described are possible without departing from the inventive concepts herein. The inventive subject matter, therefore, is not to be restricted except in the spirit of the disclosure. Moreover, in interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A thermal interface material, comprising:
at least one matrix material component,
at least one high conductivity filler component,
at least one solder material; and
at least one material modification agent, wherein the at least one material modification agent improves the thermal performance, compatibility, physical quality or a combination thereof of the thermal interface material.

2. The thermal interface material of claim 1, wherein the at least one matrix material comprises a siloxane-based component.

3. The thermal interface material of claim 2, wherein the at least one matrix material further comprises an epoxy component.

4. The thermal interface material of claim 1, wherein the at least one matrix material component is cured to form a matrix material.

5. The thermal interface material of claim 4, wherein a linear chain length of the matrix material is increased by using at least one high molecular weight linear matrix material component.

6. The thermal interface material of claim 5, wherein the linear chain length of the matrix material is increased by either hydride or vinyl terminating at least one of the at least one matrix material component.

7. The thermal interface material of claim 5, wherein the linear chain length of the matrix material is increased by decreasing a crosslinker concentration.

8. The thermal interface material of claim 1, wherein the high conductivity filler component is dispersed in the thermal interface material.

9. The thermal interface material of claim 1, wherein the at least one high conductivity filler component comprises silver, copper, aluminum, and alloys thereof; boron nitride, aluminum spheres, aluminum nitride, silver coated copper, silver coated aluminum, carbon fibers, and carbon fibers coated with metals, metal alloys, conductive polymers or other composite materials or combinations thereof.

10. The thermal interface material of claim 1, wherein the at least one high conductivity filler component comprises silver, silver-coated copper or a combination thereof in an amount of at least about 40 weight percent.

11. The thermal interface material of claim 1, wherein the at least one high conductivity filler component comprises at least two high conductivity components, wherein each component comprises a different particle size distribution from the other components.

12. The thermal interface material of claim 11, wherein each of the high conductivity filler components are selected such that the mixture forms a bimodal particle size distribution or a trimodal particle size distribution.

13. The thermal interface material of claim 1, wherein the at least one solder material comprises indium, silver, copper, aluminum, tin, bismuth, lead, gallium and combinations or alloys thereof.

14. The thermal interface material of claim 13, wherein the at least one solder material comprises tin, bismuth, indium or a combination thereof.

15. The thermal interface material of claim 1, wherein the at least one solder material comprises solder particles.

16. The thermal interface material of claim 1, wherein the at least one material modification agent comprises at least one inhibitor.

17. The thermal interface material of claim 16, wherein the at least one inhibitor comprises a diol component, a triol component, a tetraol component, a carboxylic acid-based component, a plurality of small molecules that will coordinate with at least one coordination metal or a combination thereof.

18. The thermal interface material of claim 17, wherein the diol component comprises 3-hexylene-2,5-diol.

19. The thermal interface material of claim 17, wherein the at least one coordination metal comprises platinum.

20. The thermal interface material of claim 16, wherein the at least one inhibitor is designed to extend the pot life of the thermal interface material, increase the elasticity of the matrix material, inhibit polymerization of the matrix material or a combination thereof.

21. The thermal interface material of claim 1, wherein the at least one material modification agent comprises a polyol component, a carboxylic acid-containing molecule, an epoxy-functionalized siloxane material or a combination thereof.

22. The thermal interface material of claim 21, wherein the polyol component comprises a polyalkene glycol.

23. The thermal interface material of claim 22, wherein the polyalkene glycol comprises polypropylene glycol or polyethylene glycol.

24. The thermal interface material of claim 21, wherein the carboxylic acid-containing molecule comprises stearic acid or oleic acid.

25. The thermal interface material of claim 21, wherein the epoxy-functionalized siloxane material is designed to enhance adhesion to a substrate.

26. The thermal interface material of claim 1, wherein the at least one material modification agent comprises at least one modified thermal filler profile.

27. The thermal interface material of claim 26, wherein the at least one modified thermal filler profile comprises a plurality of incorporatable thermal fillers that are designed to optimize the particle size distribution in the thermal interface material.

28. The thermal interface material of claim 27, wherein optimizing the particle size distribution includes maximizing the volume fraction loading.

29. The thermal interface material of claim 28, wherein maximizing the volume fraction loading includes a volume fraction loading of at least 60 volume percent.

30. The thermal interface material of claim 28, wherein maximizing the volume fraction loading includes a volume fraction loading of at least 65 volume percent.

31. The thermal interface material of claim 28, wherein maximizing the volume fraction loading includes a volume fraction loading of at least 70 volume percent.

32. The thermal interface material of claim 1, wherein the at least one high conductivity filler component and the at least one solder component are selected so that the mixture forms a bimodal particle size distribution or a trimodal particle size distribution.

33. The thermal interface material of claim 1, wherein at least one of the at least one high conductivity filler component comprises particles having a diameter of less than about 80 μm and the mean size of the high conductivity particles is larger than the mean particle size of the solder particles.

34. The thermal interface material of claim 33, wherein the at least one high conductivity filler component comprises particles having a diameter of less than about 50 μm.

35. The thermal interface material of claim 1, wherein at least one of the at least one high conductivity filler and the at least one solder material is coated with a carboxylic acid-containing molecule prior to incorporation into the thermal interface material.

36. The thermal interface material of claim 1, wherein a carboxylic acid group or its precursor is incorporated into the at least one matrix material.

37. The thermal interface material of claim 36, wherein the carboxylic acid group or its precursor is incorporated onto the at least one matrix material as a side group substituent or as a terminal group substituent.

38. The thermal interface material of claim 1, wherein the thermal interface material comprises metal flakes, sintered metal flakes or a combination thereof.

39. The thermal interface material of claim 1, wherein the thermal interface material has a thermal conductivity of greater than about 3 W/m-K.

40. The thermal interface material of claim 39, wherein the thermal interface material has a thermal conductivity of greater than about 10 W/m-K.

41. The thermal interface material of claim 40, wherein the thermal interface material has a thermal conductivity of greater than about 20 W/m-K.

42. A method of forming a thermal interface material, comprising:
providing each of the at least one matrix material, at least one high conductivity filler, at least one solder material and at least one material modification agent,
blending the components; and
optionally curing the components pre- or post-application of the thermal interface material to the surface, substrate or component.

43. The method of claim 42, wherein the cured thermal interface material is no crosslinked.

44. A thermal interface material, comprising:
at least one matrix material,
at least one high conductivity filler component,
at least one solder material; and
at least one material modification agent, wherein the at least one material modification agent at least one modified thermal filler profile.

45. The thermal interface material of claim 44, wherein the at least one modified thermal filler profile comprises a plurality of incorporatable thermal fillers that are designed to optimize the particle size distribution for the highest possible volume fraction loading.
